(19) United States
(12) Patent Application Publication
(10) Pub. No.: US 2012/0169382 A1
(43) Pub. Date: Jul. 5, 2012

(54) DIVIDING METHOD AND DIVIDING APPARATUS FOR GENERATING NOISE-REDUCED FREQUENCY DIVIDED SIGNAL BY UTILIZING NOISE REDUCING CIRCUIT

(76) Inventor: Shuo-Chun Hung, Taichung City (TW)

(21) Appl. No.: 13/179,571

(22) Filed: Jul. 11, 2011

(30) Foreign Application Priority Data
Dec. 29, 2010 (TW) 099146579

(51) Int. Cl. H03K 21/00

(52) U.S. Cl. 327/115

(57) ABSTRACT

A dividing apparatus is provided. The dividing apparatus includes a frequency dividing circuit and a noise reducing circuit. The frequency dividing circuit is arranged to receive a first clock signal and generate a frequency divided signal corresponding to the first clock signal. The noise reducing circuit is coupled to the frequency dividing circuit and arranged to receive a second clock signal and the frequency divided signal, and is utilized for referring to the second clock signal and the frequency divided signal to reduce noise of the frequency divided signal to generate a noise-reduced frequency divided signal. The first and second clock signals may be identical clock signals or different clock signals.

### BACKGROUND OF THE INVENTION

1. Field of the Invention

The present invention relates to a dividing mechanism, and more particularly, to a dividing apparatus operated in a high-speed/high-frequency environment and capable of reducing jitter effectively and related dividing method thereof.

2. Description of the Prior Art

Generally, circuit structures utilized in traditional dividing apparatuses are complementary metal oxide semiconductor standard cell (CMOS Standard Cell) based circuit structures. However, in order to improve circuitry's resistance to jitter, some dividing apparatuses utilize current mode logic (CML) based circuit structures to replace the original CMOS standard cell based circuit structures. Such an implementation, however, will comparatively increase the chip area as well as the power consumption. But under some certain situations (e.g., high-speed/high-frequency operation environments), the currently used CML based circuit structure still fails to effectively improve the noise immunity against jitter.

### SUMMARY OF THE INVENTION

Therefore, one of the objectives of the present invention is to provide a dividing apparatus operated in a high-speed/high-frequency environment and capable of reducing jitter effectively and related dividing method thereof to solve the aforementioned problem.

According to an exemplary embodiment of the present invention, a dividing apparatus is disclosed. The dividing apparatus includes a first frequency dividing circuit and a first noise reducing circuit. The first frequency dividing circuit is utilized for receiving a first clock signal and generating a first frequency divided signal corresponding to the first clock signal. The first noise reducing circuit is coupled to the first frequency dividing circuit, for receiving a second clock signal and the first frequency divided signal, and refers to the second clock signal and the first frequency divided signal to reduce noise of the first frequency divided signal, thereby generating a first noise-reduced frequency divided signal.

According to another exemplary embodiment of the present invention, a dividing method is disclosed. The dividing method includes: receiving a first clock signal, and generating a first frequency divided signal corresponding to the first clock signal; utilizing a first noise reducing circuit for receiving a second clock signal and the first frequency divided signal, and referring to the second clock signal and the first frequency divided signal to reduce noise of the first frequency divided signal for generating a first noise-reduced frequency divided signal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a block diagram illustrating a dividing apparatus according to a first exemplary embodiment of the present invention.

FIG. 2A is a circuit diagram of the dividing apparatus shown in FIG. 1.

FIG. 2B is a diagram illustrating a circuit structure of an actual implementation of the frequency dividing circuit shown in FIG. 1.

FIG. 2C is a diagram illustrating a circuit structure of an actual implementation of the noise reducing circuit shown in FIG. 1.

FIG. 3 is a diagram illustrating signal waveforms of the clock signal CK, the signal S1, the frequency divided signal S2 and the noise-reduced frequency divided signal DIV2 shown in FIG. 1.

FIG. 4 is a block diagram illustrating a dividing apparatus according to a second exemplary embodiment of the present invention.

FIG. 5 is a circuit diagram of the dividing apparatus shown in FIG. 4.

FIG. 6 is a diagram illustrating signal waveforms of the clock signal CK, the signals S1-S4, and the noise-reduced frequency divided signals DIV2 and DIV4 shown in FIG. 4.

FIG. 7 is a circuit diagram of a dividing apparatus according to a third exemplary embodiment of the present invention.

FIG. 8 is a diagram illustrating a circuit structure of an actual implementation of the noise reducing circuit shown in FIG. 7.

FIG. 9 is a diagram illustrating signal waveforms of the clock signal CK, the signal S1, the frequency divided signal S2 and the noise-reduced frequency divided signal DIV2 shown in FIG. 7.

FIG. 10 is a circuit diagram of a dividing apparatus according to a fourth exemplary embodiment of the present invention.

FIG. 11 is a diagram illustrating signal waveforms of the clock signal CK, the signals S1-S4, and the noise-reduced frequency divided signals DIV2 and DIV4 shown in FIG. 10.

### DETAILED DESCRIPTION

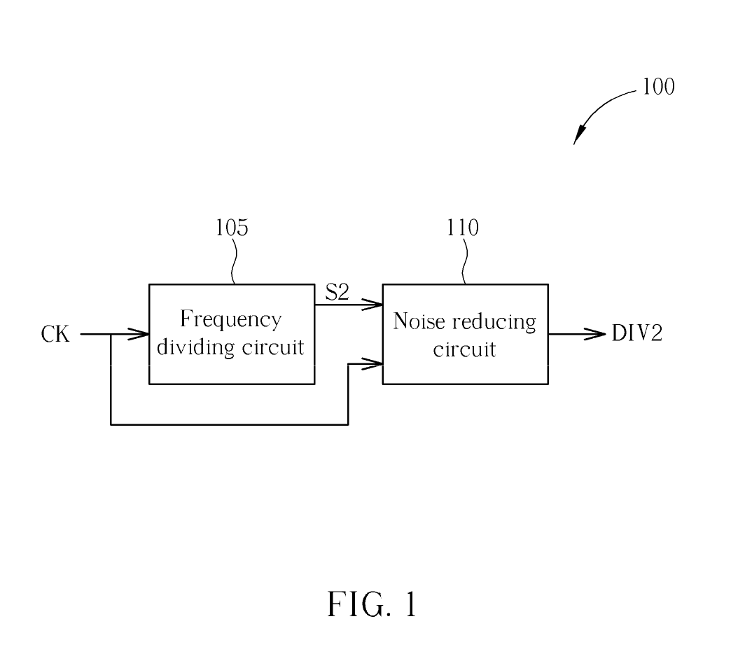

Please refer to FIG. 1, which is a block diagram illustrating a dividing apparatus 100 according to a first exemplary embodiment of the present invention. The dividing apparatus 100 includes a frequency dividing circuit 105 and a noise reducing circuit 110. The frequency dividing circuit 105 is utilized for receiving a first clock signal and generating a frequency divided signal S2 corresponding to the first clock signal. The noise reducing circuit 110 is coupled to the frequency dividing circuit 105, and utilized for receiving a second clock signal and the frequency divided signal S2, and referring to the second clock signal and the frequency divided signal S2 to reduce noise of the frequency divided signal S2, thereby generating a noise-reduced frequency divided signal DIV2. In this exemplary embodiment, signal sources of the first clock signal and the second clock signal both are an identical clock signal source CK. In other words, the second clock signal is the first clock signal received by the frequency dividing circuit 105, and the signal source thereof is the signal source CK which also provides the first clock signal, as shown in FIG. 1. Besides, the dividing apparatus 100 may be operated in a high-speed (or high-frequency) environment, and have tolerance of more jitter. That is, the dividing apparatus 100 has favorable noise immunity against jitter. In an actual application, the frequency dividing circuit 105 is realized by utilizing a CML based circuit structure. The CML based circuit structure is capable of reducing jitter of a signal. However, under certain situations (e.g., high-speed or high-frequency operation environments), signals that are not frequency-divided yet/signals that have been frequency-divided still have too much jitter. Therefore, the noise reducing circuit 110 in this exemplary embodiment is designed to perform a noise reducing operation upon the frequency divided signal S2 to reduce jitter of the frequency divided signal S2 effectively and accordingly generate a noise-reduced frequency divided signal DIV2. Though the naming of the noise reducing circuit 110 includes the term “noise reducing”, it represents that the noise reducing circuit 110 itself may reduce jitter of a signal effectively or may even substantially eliminate jitter of a signal. That is, “noise reducing” is not required to exactly eliminate jitter of a signal. Similarly, the jitter within the noise-reduced frequency divided signal DIV2 is effectively lower than the jitter within the frequency divided signal S2. Particularly, the jitter within the corresponding signal source may be eliminated substantially.

Moreover, one of the objectives of the present invention is to reduce jitter resulted from a CML based circuit operating under a high-speed or high-frequency environment. However, it should be noted that the frequency dividing circuit 105 in the dividing apparatus 100 is not necessarily realized by utilizing a CML based circuit structure. That is, the CML based circuit structure is merely a preferred circuit structure in the current exemplary embodiment, and is not meant to be a limitation of the present invention. Besides, the frequency of the noise-reduced frequency divided signal DIV2 is substantially identical to the frequency of the frequency divided signal S2. However, the duty cycle of the noise-reduced frequency divided signal DIV2 may be identical to or different from the duty cycle of the frequency divided signal S2, depending on the design choice of the circuit. Thus, these alternative designs all fall within the scope of the present invention.

Moreover, in this exemplary embodiment, the frequency of the frequency divided signal S2 generated by the frequency dividing circuit 105 is half of the frequency of the clock signal CK. However, it is only one design choice utilized for illustrating the frequency dividing operation and noise reducing operation of the exemplary embodiment, and is not meant to be a limitation of the present invention. In other exemplary embodiments, the frequency dividing circuit 105 may be particularly designed such that the frequency of the clock signal CK is N times as large as the frequency of the frequency divided signal S2 generated by the frequency dividing circuit 105, wherein N is any number that is larger than zero.

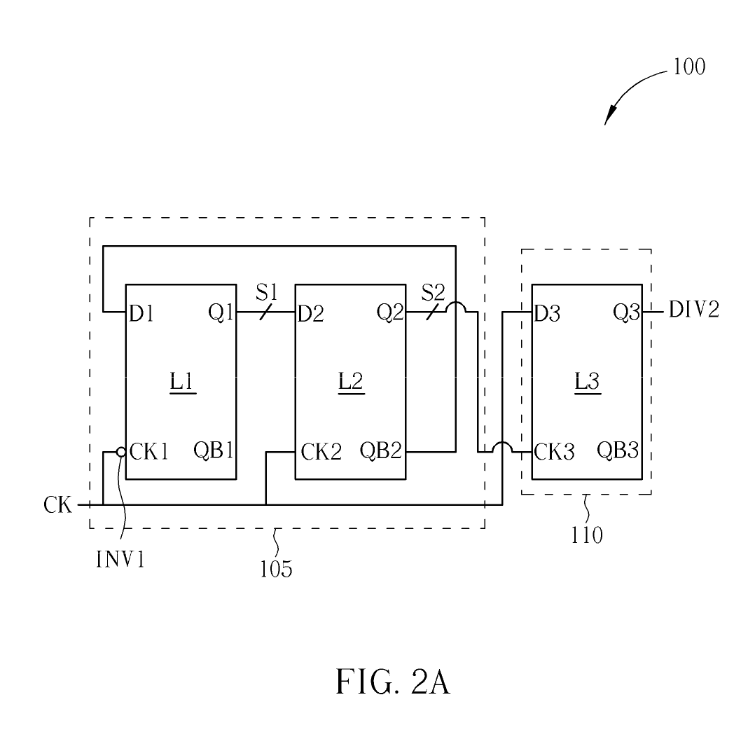

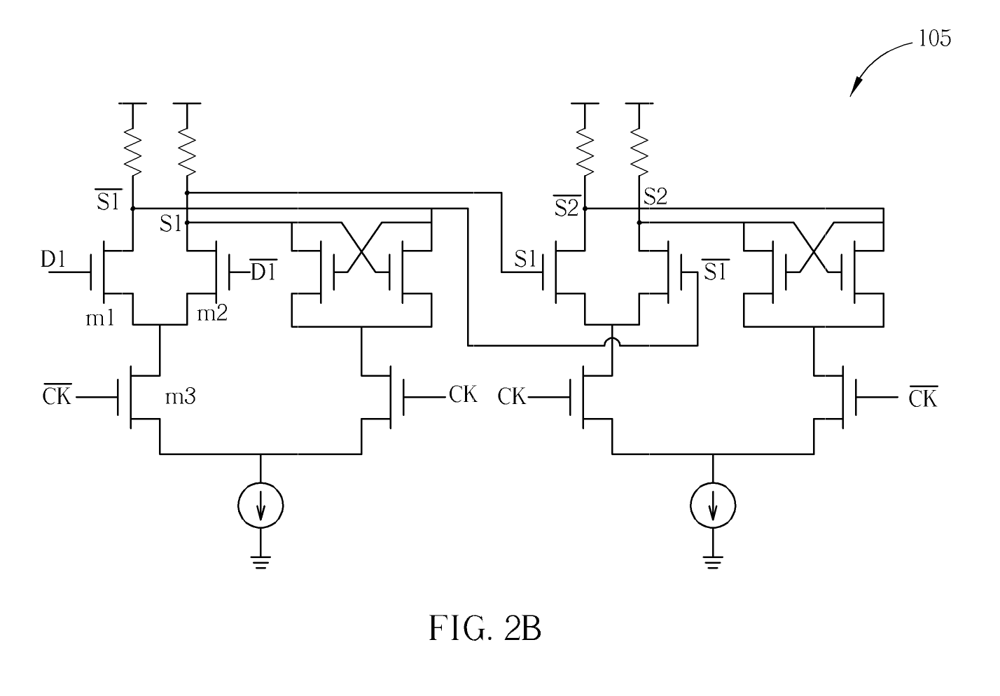

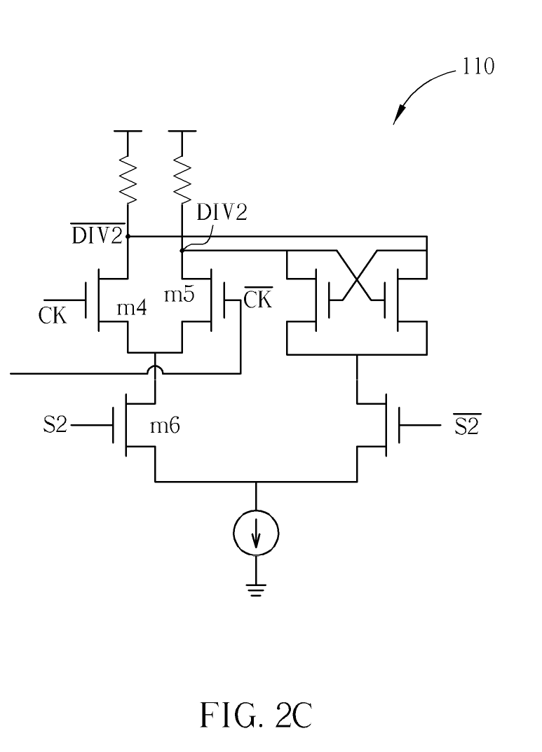

Please refer to FIG. 2A, which is a circuit diagram of the dividing apparatus 100 shown in FIG. 1. As shown in FIG. 2A, the frequency dividing circuit 105 includes latch units L1 and L2, and an inverter INV1 which is electrically connected to the latch unit L1. The noise reducing circuit 110 includes a latch unit L3, wherein the latch units L1, L2 and L3 are delay latches (or called transparent latches). The latch units L1, L2 and L3 have clock input terminals CK1-CK3, data input terminals D1-D3, data output terminals Q1-Q3 and inverted data output terminal QB1-QB3. Signal transmission and circuit interconnection relations are illustrated below.

The data input terminal D1 of the latch unit L1 is coupled to the inverted data output terminal QB2 of the latch unit L2. The data output terminal Q1 of the latch unit L1 is coupled to the data input terminal D2 of the latch unit L2. The clock signal CK is input to the output terminal of the inverter INV1, and is output to the clock input terminal CK1 of the latch unit L1 after being inverted. The latch units L1 and L2 form a D type Flip-Flop. Meanwhile, the clock signal CK is also input to the clock input terminal CK2 of the latch unit L2. The frequency divided signal S2 is generated at the data output terminal Q2 of the latch unit L2. The clock signal CK may be regarded as an input signal of the frequency dividing circuit 105, and the frequency divided signal S2 may be regarded as an output signal of the frequency dividing circuit 105.

Please refer to FIG. 2B, which is a diagram illustrating a circuit structure of an actual implementation of the frequency dividing circuit 105 shown in FIG. 1. As shown in FIG. 2B, the frequency dividing circuit 105 utilizes a CML based circuit structure. As aforementioned, the objective of utilizing the CML based circuit structure to realize the frequency dividing circuit 105 is to improve the noise immunity against jitter. However, in a high-speed or high-frequency operation environment, since a transistor in the CML based circuit is not operated in a saturation region, the resistance to common mode noise and power noise is poor even though a CML based circuit structure is utilized to realize the frequency dividing circuit. For example, the clock signal CK has a higher frequency. When the clock signal CK has a transition from one logic level “0” to another logic level “1” or from one logic level “1” to another logic level “0” (i.e., the clock signal CK has signal level transition), the output data also starts performing level transition. At this moment, the whole circuit is most sensitive to noise interference. However, as electrical characteristics of circuit components are not fully symmetrical (e.g., one of the transistors m1 and m2 is switched off first, whereas the other of the transistors m1 and m2 and the transistor m3 are still conductive), the transistors m1, m2 and m3 in this situation would act as transmission gates rather than operated in the saturation region. Therefore, the noise immunity against jitter is not improved.

Please refer to FIG. 2C, which is a diagram illustrating a circuit structure of an actual implementation of the noise reducing circuit 110 shown in FIG. 1. As shown in FIG. 2C, the noise reducing circuit 110 also utilizes the CML based circuit structure. However, transistors m4-m6 in the CML based circuit structure of the noise reducing circuit 110 are capable of operating in the saturation region. Therefore, in a high-speed or high-frequency operation environment, the circuit would still have good noise immunity against jitter. This is because the frequency divided signal S2 which has a lower frequency is connected to the gate of the transistor m6 (i.e., the clock input terminal CK3 of the latch unit L3), and the clock signal CK is connected to the gates of the transistors m4 and m5 (i.e., the data input terminal D3 of the latch unit L3). Therefore, during the signal level transition operation, the transistors m4-m6 do not act as transmission gates and may be operated in the saturation region. In this way, the circuit has higher noise immunity against jitter.

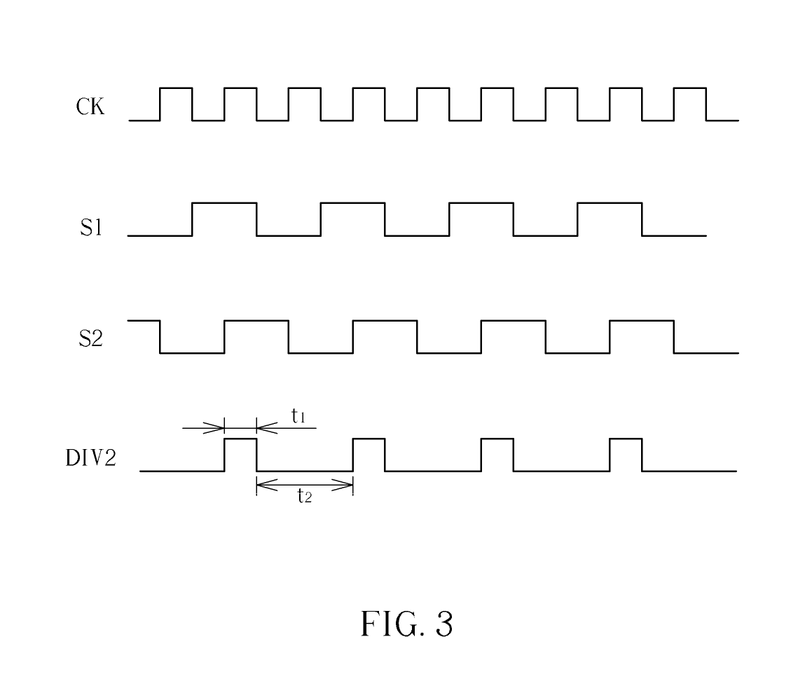

Please refer to FIG. 3, which is a diagram illustrating signal waveforms of the clock signal SK, the signal S1, the frequency divided signal S2 and the noise-reduced frequency divided signal DIV2 shown in FIG. 1. As shown in FIG. 3, the frequency of the frequency divided signal S2 is half of the frequency of the clock signal CK. The aforementioned transistors m1-m3 are not operated in the saturation region, so the frequency divided signal S2 has much noise. Therefore, this exemplary embodiment utilizes the noise reducing circuit 110 to reduce noise in the frequency divided signal S2 and accordingly generate a noise-reduced frequency divided signal DIV2 which has less noise. Please refer to FIG. 3 together with FIG. 2A. The clock input terminal CK3 of the latch unit L3 receives the frequency divided signal S2, and the data input terminal D3 of the latch unit L3 receives the clock signal CK. Therefore, when the frequency divided signal S2 shown in FIG. 3 has a transition from one logic level “0” to another logic level “1”, the instant signal level of the clock signal CK is generated at the data output terminal Q3 via the latch unit L3. When the frequency divided signal S2 shown in FIG. 3 has a transition from the logic level “1” to the logic level “0”, the instant signal level of the clock signal CK is not transmitted through the latch unit L3, and the latch unit L3 maintains/latches the previously generated data value at its data output terminal Q3. Therefore, the circuit may generate the noise-reduced frequency divided signal DIV2 with a waveform shown in FIG. 3. The noise-reduced frequency divided signal DIV2 has a high logic level during period t1, and has a low logic level during period t2. Though the waveform of the noise-reduced frequency divided signal DIV2 in this exemplary embodiment does not have a 50% duty cycle, an additional circuit design (e.g., a low-speed frequency divider) may be implemented to make the noise-reduced frequency divided signal DIV2 have a 50% duty cycle; however, this is not meant to be a limitation of the present invention. Please note that the frequency divided signal S2 has higher jitter; however, when the clock signal CK performs signal level transition, the signal level of the frequency divided signal S2 is stable and does not have a large variation, and the jitter of the frequency divided signal S2 will not be transmitted to the data output terminal Q3 of the latch unit L3. So, the circuit structure shown in FIG. 2 may greatly improve the noise immunity against jitter.

Besides, though the aforementioned exemplary embodiment utilizes the latch unit L3 to realize the noise reducing circuit 110, it is merely a design choice of the exemplary embodiment, and is not meant to be a limitation of the present invention. In other exemplary embodiments, the noise reducing circuit may be realized by utilizing other circuits. For example, a sampling circuit may be utilized to realize the noise reducing circuit 110. In other words, the noise reducing circuit 110 has the signal sampling ability, and refers to a signal level transition point of the frequency divided signal S2 (e.g., the time point at which a transition from the logic level “0” to another logic level “1” occurs) to sample the clock signal CK, thereby generating the noise-reduced frequency divided signal DIV2. That is, any circuit component with signal sampling ability may be utilized as the noise reducing circuit 110 in the exemplary embodiment, which falls in the scope of the present invention.

Besides, though the aforementioned exemplary embodiment utilizes the latch unit L3 to realize the noise reducing circuit 110, other types of latch units may be utilized in other exemplary embodiments to realize the function and operation (i.e., the data latching operation) of the noise reducing circuit 110. So, the use of the latch unit L3 is not meant to be a limitation of the present invention. Moreover, the frequency dividing circuit 105 in this exemplary embodiment is realized by a D type Flip-Flop. However, as the output terminal of the frequency dividing circuit 105 is coupled to the noise reducing circuit 110, and jitter in the signal may be reduced via the noise reducing circuit 110, the design of the frequency dividing circuit 105 in an actual implementation only requires that the frequency dividing circuit 105 is capable of performing the signal frequency dividing operation correctly, and does not particularly require that the frequency dividing circuit 105 should be noise-resistant. So, in an actual application, the frequency dividing circuit 105 may be implemented by power-efficient and small-sized circuit components.

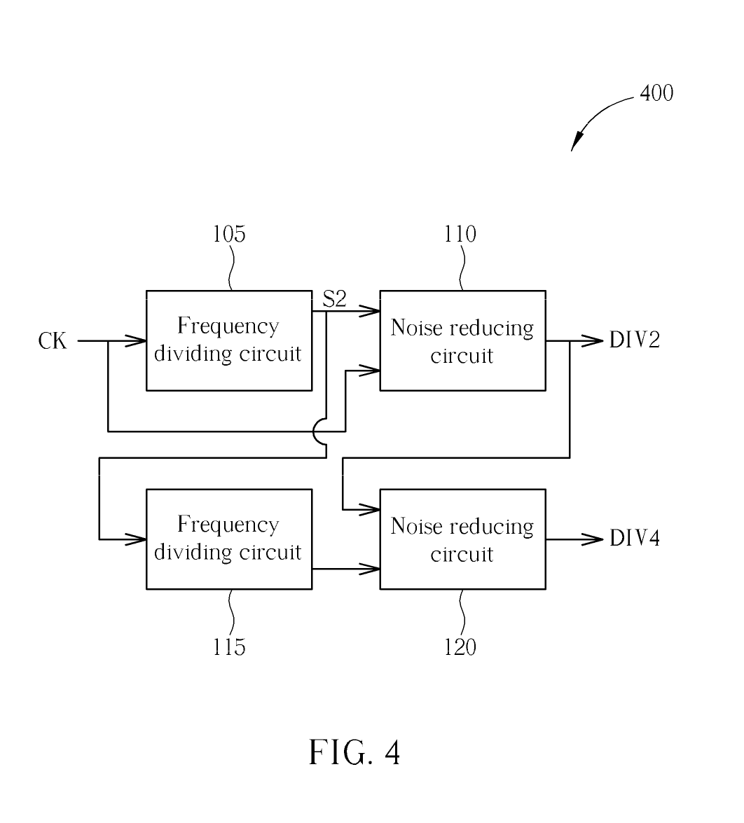

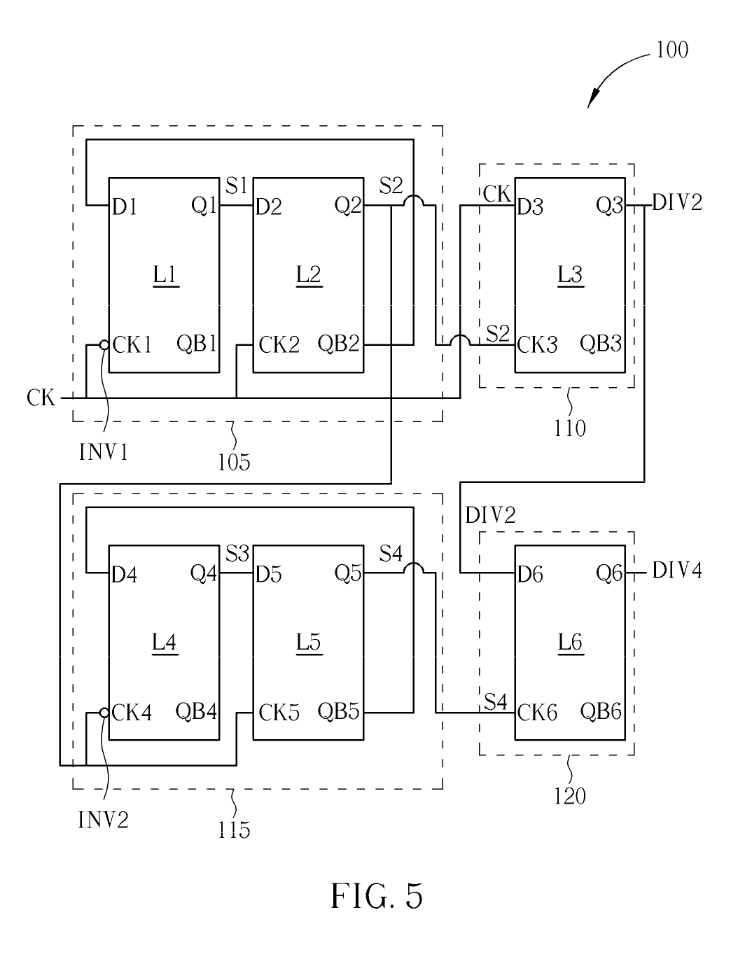

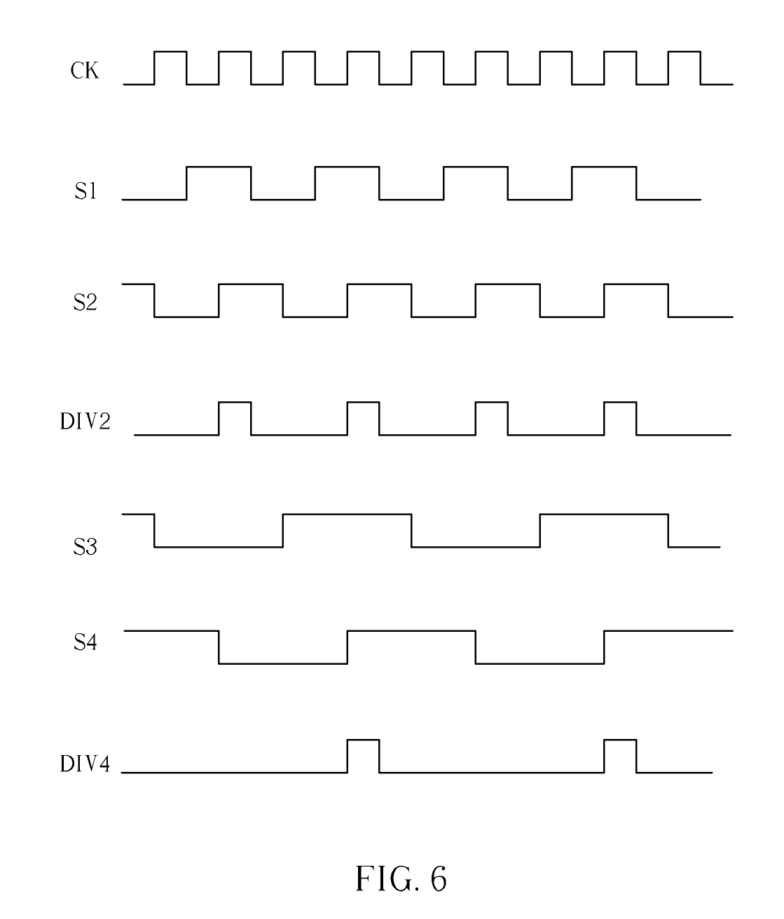

Please refer to FIG. 4, which is a block diagram illustrating a dividing apparatus 400 according to a second exemplary embodiment of the present invention. The dividing apparatus 400 includes a frequency dividing circuit 105, a noise reducing circuit 110, a frequency dividing circuit 114 and a noise reducing circuit 120. As circuit design, function and operation of the frequency dividing circuit 115 and the noise reducing circuit 120 are identical to that of the frequency dividing circuit 105 and the noise reducing circuit 110, respectively, further description is omitted here for brevity. The circuit diagram of the dividing apparatus 400 is shown in FIG. 5. The difference between the dividing apparatuses 100 and 400 is that the inverter INV2 receives the frequency divided signal S2 generated at the data output terminal Q2 of the latch unit L2 within the frequency dividing circuit 105, and the frequency divided signal S2 is input to the clock input terminal CK4 of the latch unit L4 within the second frequency dividing circuit 115 after inverted. Besides, the frequency divided signal S2 is also input to the clock input terminal CK5 of the latch unit L5 within the frequency dividing circuit 115, the output signal of the frequency dividing circuit 115 is a frequency divided signal S4 generated by the data output terminal Q5 of the latch unit L5, the signal S4 will be output to the clock input terminal CK6 of the latch unit L6 within the noise reducing circuit 120, and the latch unit L6 utilizes its data input terminal D6 to receive a noise-reduced frequency divided signal DIV2 generated by the noise reducing circuit 110. Therefore, as to the frequency dividing circuit 115 and the noise reducing circuit 120, the frequency dividing circuit 115 receives and refers to the frequency divided signal S2 generated by a preceding frequency dividing circuit 105 to perform frequency dividing operation. The noise reducing circuit 120 generates a noise-reduced frequency divided signal DIV4 by referring to the frequency divided signal S4 generated by the frequency dividing circuit 115 and the noise-reduced frequency divided signal DIV2 generated by the previous noise reducing circuit 110. The frequency of the frequency divided signal S4 is half of the frequency divided signal S2 (i.e., the frequency of the frequency divided signal S4 is one-fourth of the clock signal CK). In other words, the noise reducing circuit 120 reduces the frequency of sampling the clock signal by referring to the signal level transition points of the frequency divided signal S4 (please note that the clock signal is the noise-reduced frequency divided signal DIV2 generated by the noise reducing circuit 110), and the frequency of the generated noise-reduced frequency divided signal DIV4 is one-fourth of the frequency of the clock signal CK. Please refer to FIG. 6 for waveforms of the signals S3, S4 and DIV4. However, the aforementioned embodiment is only a design choice utilized for illustrating the frequency dividing operation and noise reducing operation easily, and is not meant to be a limitation of the present invention. In other exemplary embodiment, the frequency dividing circuit 115 may be particularly designed such that the frequency of the clock signal CK is M times as large as the frequency of the frequency divided signal S4 generated by the frequency dividing circuit 115, wherein M is a positive integer larger than or equal to five. As aforementioned, the clock signal S2 received by the frequency dividing circuit 115 is not identical to the clock signal DIV2 received by the noise reducing circuit 120. That is, their signal sources are not an identical signal source.

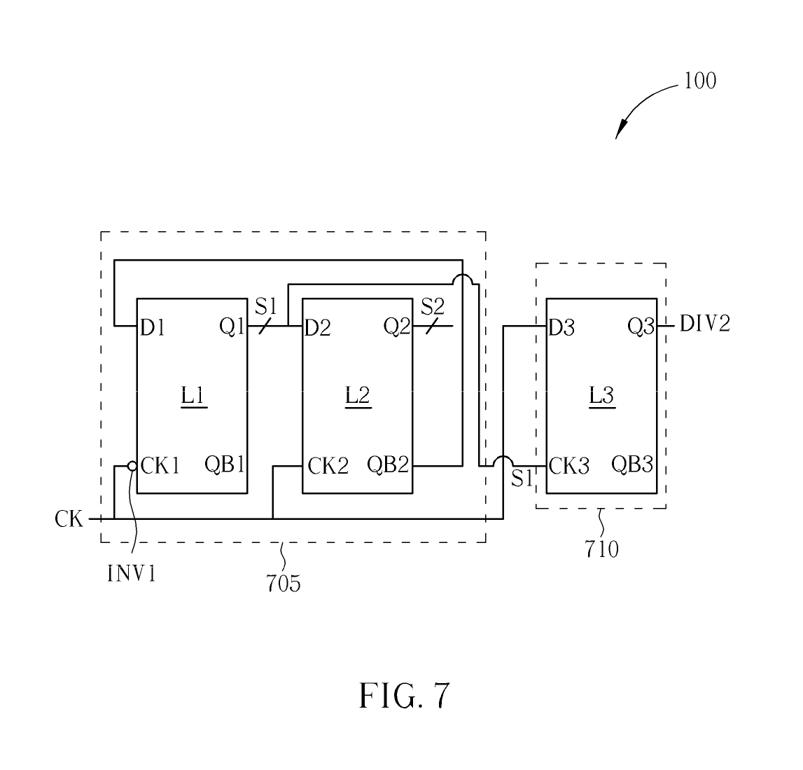

Besides, in an actual application, noise may be further reduced by properly adjusting phases of the frequency divided signals S1 and S2. In other exemplary embodiments, the frequency divided signal S1 generated by the latch unit L1 may also be selected as an output signal of the frequency dividing circuit. Please refer to FIG. 7, which is a circuit diagram illustrating a diving apparatus 700 according to a third exemplary embodiment of the present invention. As shown in FIG. 7, the dividing apparatus 700 includes a frequency dividing circuit 705 and a noise reducing circuit 710, wherein the operation and function of the inner components (e.g., a plurality of latch units) of the frequency dividing circuit 705 and the noise reducing circuit 710 are identical to that of the inner components of the frequency dividing circuit 105 and the noise reducing circuit 110 shown in FIG. 2A. Further description is therefore omitted here for brevity. The difference is that the data output terminal Q1 of the latch unit L1 within the frequency dividing circuit 705 is coupled to the clock input terminal CK3 of the latch unit L3 within the noise reducing circuit 710, and the frequency divided signal S1 generated by the data output terminal Q1 is directly fed into the clock input terminal CK3 of the latch unit L3.

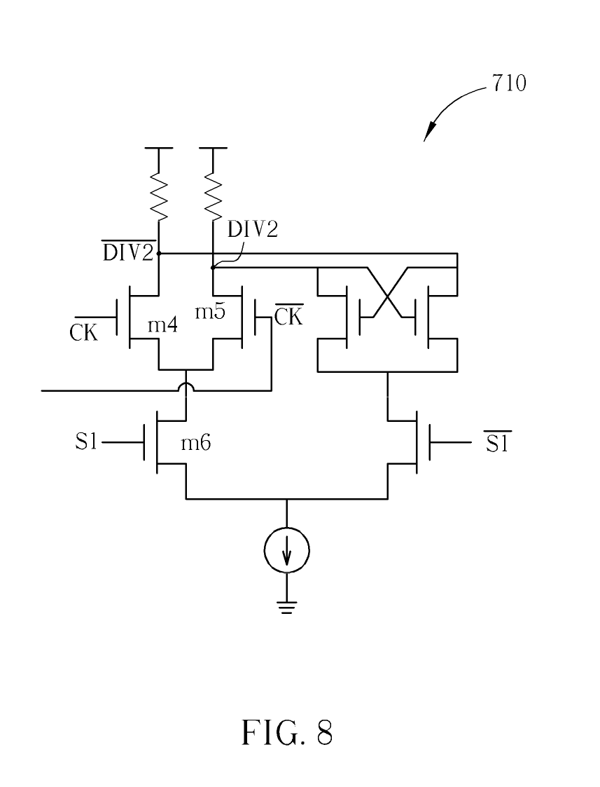

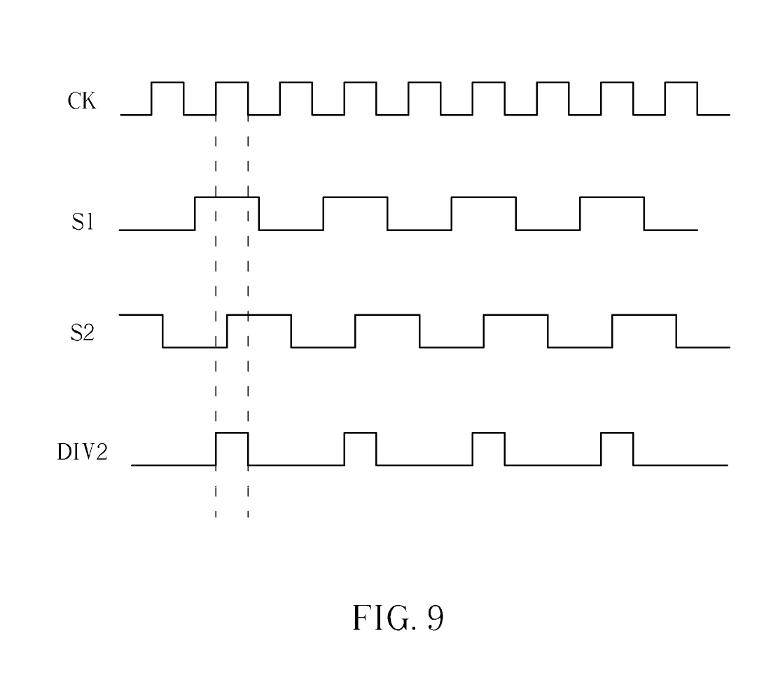

Please refer to FIG. 9 together with FIG. 8. FIG. 8 is a diagram illustrating a circuit structure of an actual implementation of the noise reducing circuit 700 shown in FIG. 7. FIG. 9 is a diagram illustrating signal waveforms of the clock signal CK, the signal S1, the frequency divided signal S2 and the noise-reduced frequency divided signal DIV2 shown in FIG. 7. In an actual application, the frequency divided signals S1 and S2 respectively generated by the latch units L1 and L2 may have certain phase delay. As shown in FIG. 9, there is a phase delay between the frequency divided signal S1 shown in FIG. 9 and the frequency divided signal S1 shown in FIG. 3 when the phase of the frequency divided signal S1 shown in FIG. 9 is compared with the phase of the frequency divided signal S1 shown in FIG. 3; additionally, there is another phase delay between frequency divided signals S1 and S2 shown in FIG. 9. At the instant that the frequency divided signal S1 is at a high logic level such that the transistor m6 shown in FIG. 8 is conductive, the signal level of the clock signal CK does not have any level transition. When the signal level of the clock signal CK has a level transition, the frequency divided signal S1 is at a high logic level stably. Therefore, the transistors m4-m6 within the CML based circuit of the noise reducing circuit 710 are operated in the saturation region, and therefore have good noise immunity against jitter in a high-speed or high-frequency operation environment. This is because the transistors m4-m6 do not act as transmission gates during the signal level transition operation, leading to higher noise immunity against jitter.

Please note that, when the problem resulted from different phase delays in the actual circuits is considered, in order to ensure that the transistors m4-m6 are operated in saturation region when the clock signal CK has signal level transition, those skilled in the art may feed any one selected from the frequency divided signals S1 and S2 which has a more proper phase into the clock input terminal CK3 of the latch unit L3 in accordance with teachings of the present invention. Besides, any one of the frequency divided signals S1 and S2 may be delayed by a certain delay amount (which is not meant to be a limitation of the present invention) and then fed into the clock input terminal CK3 of the latch unit L3, in order to further ensure that the transistors m4-m6 are operated in the saturation region when the clock signal CK has signal level transition.

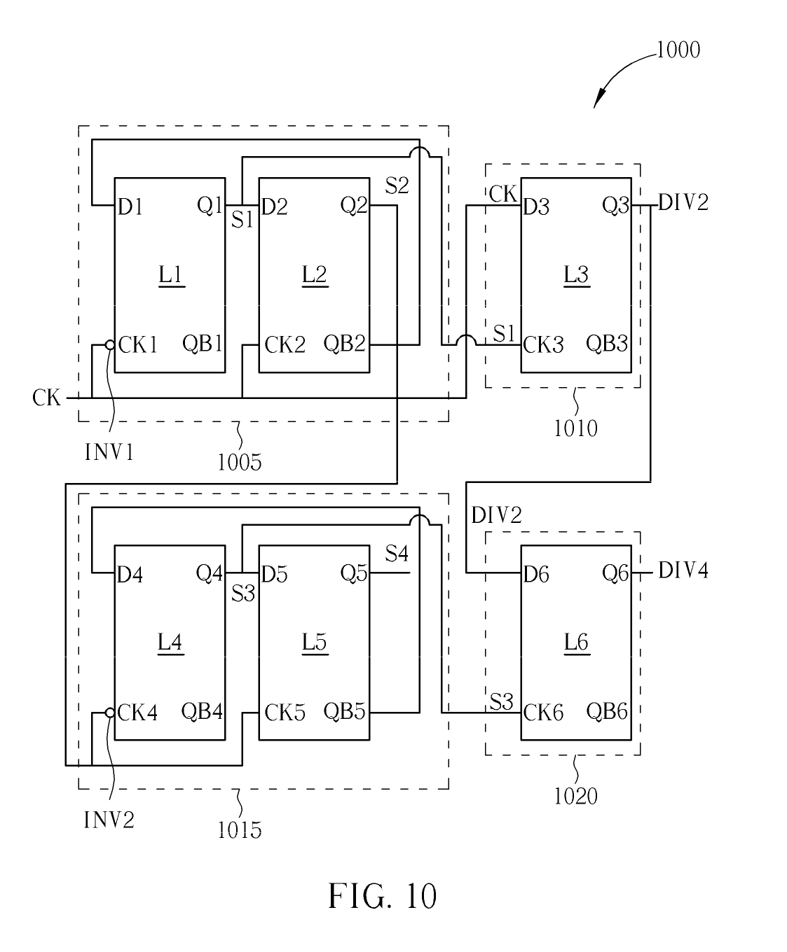

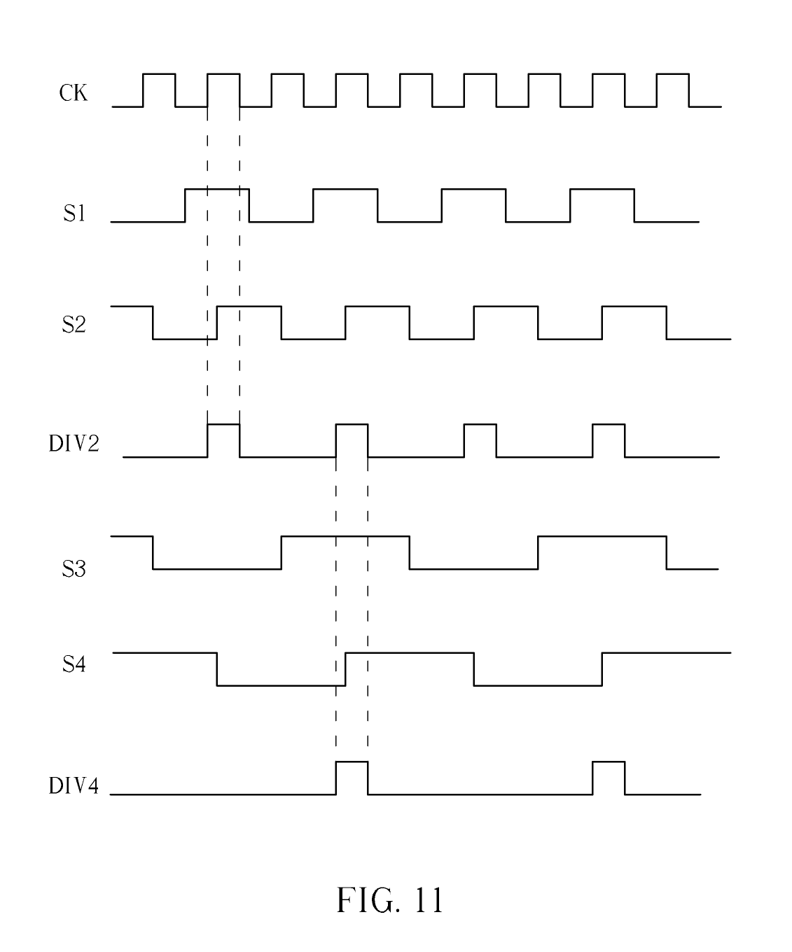

Moreover, please refer to FIG. 11 together with FIG. 10. FIG. 10 is a circuit diagram illustrating a diving apparatus according to a fourth exemplary embodiment of the present invention. FIG. 11 is a diagram illustrating signal waveforms of the clock signal CK, the signals S1-S4, and the noise-reduced frequency divided signals DIV2 and DIV4 shown in FIG. 10. The dividing apparatus 1000 includes frequency dividing circuits 1005 and 1015, and noise reducing circuits 1010 and 1020, wherein the function and operation of the inner components (e.g. a plurality of latch units) of the frequency dividing circuits 1005 and 1015 and the noise reducing circuits 1010 and 1020 are identical to that of the frequency dividing circuits 105 and 115 and the noise reducing circuits 110 and 120 shown in FIG. 5, respectively. Further description is therefore omitted here for brevity. The difference is that the data output terminal Q1 within the latch unit L1 of the frequency dividing 1005 is coupled to the clock input terminal CK3 within the latch unit L3 of the noise reducing circuit 1010, the frequency divided signal S1 generated by the data output terminal Q1 is directly fed into the clock input terminal CK3 of the latch unit L3, the data output terminal Q4 of the latch unit L4 within the frequency dividing circuit 1015 is coupled to the clock input terminal CK6 of the latch unit L6 within the noise reducing circuit 1020, and the frequency divided signal S3 generated by the data output terminal Q4 is directly fed into the clock input terminal CK6 of the latch unit L6. Similar to signals shown in FIG. 9, in an actual application, the frequency divided signals S1, S2, S3, S4 respectively generated by the latch units L1, L2, L3, L4 may have certain phase delays. As shown in FIG. 11, there are phase delays between the frequency divided signals S1-S4 shown in FIG. 11 and the frequency divided signals S1-S4 shown in FIG. 5 when phases of the frequency divided signals S1-S4 shown in FIG. 11 are respectively compared with phases of the frequency divided signals S1-S4 shown in FIG. 5. At the instant the signal levels of frequency divided signals S1 and S3 have transitions to the high logic level, the signal level of the clock signal CK has no signal level transition. When the clock signal CK has signal level transition, the frequency divided signal S1 is at a high logic level stably. Therefore, transistors of the CML based circuit of the frequency reducing circuits 1010 and 1020 may be operated in the saturation region and have good noise immunity against jitter. This is because the transistors do not act as transmission gates during the signal level transition operation, and may be operated in the saturation region. In this way, the circuit would have higher noise immunity against jitter.

Those skilled in the art will readily observe that numerous modifications and alterations of the device and method may be made while retaining the teachings of the invention.

What is claimed is:

1. A dividing apparatus, comprising:
a first frequency dividing circuit, for receiving a first clock signal and generating a first frequency divided signal corresponding to the first clock signal; and
a first noise reducing circuit, coupled to the first frequency dividing circuit, for receiving a second clock signal and the first frequency divided signal, and referring to the second clock signal and the first frequency divided signal to reduce noise of the first frequency divided signal for generating a first noise-reduced frequency divided signal.

2. The dividing apparatus of claim 1, wherein the second clock signal is the first clock signal received by the first frequency dividing circuit.

3. The dividing apparatus of claim 1, further comprising:
a second frequency dividing circuit, for receiving the first frequency divided signal and generating a second frequency divided signal; and
a second noise reducing circuit, coupled to the second frequency dividing circuit, for receiving the first noise-reduced frequency divided signal and the second frequency divided signal, and referring to the first noise-reduced frequency divided signal and the second frequency divided signal to reduce noise of the second frequency divided signal for generating a second noise-reduced frequency divided signal.

4. The dividing apparatus of claim 1, wherein the first noise reducing circuit generates the first noise-reduced frequency divided signal by referring to a signal level transition point of the first frequency divided signal to sample the second clock signal.

5. The dividing apparatus of claim 4, wherein the first noise reducing circuit generates the first noise-reduced frequency divided signal by performing a data latch operation upon the second clock signal according to the first frequency divided signal.

6. The dividing apparatus of claim 5, wherein the first noise reducing circuit comprises a latch unit having a data input terminal, a data output terminal and an enabling input terminal, the first frequency divided signal is coupled to the enabling input terminal, the second clock signal is coupled to the data input terminal, and the first noise-reduced frequency divided signal is generated at the data output terminal.

7. The dividing apparatus of claim 5, wherein the latch unit is a transparent latch.

8. A dividing method, comprising:
receiving a first clock signal, and generating a first frequency divided signal corresponding to the first clock signal; and
utilizing a first noise reducing circuit for receiving a second clock signal and the first frequency divided signal, and referring to the second clock signal and the first frequency divided signal to reduce noise of the first frequency divided signal for generating a first noise-reduced frequency divided signal.

9. The dividing method of claim 8, wherein the second clock signal is identical to the first clock signal.

10. The dividing method of claim 8, further comprising:
receiving the first frequency divided signal, and dividing frequency of the first frequency divided signal for generating a second frequency divided signal; and
utilizing a second noise reducing circuit for receiving the first noise-reduced frequency divided signal and the second frequency divided signal, and referring to the first noise-reduced frequency divided signal and the second frequency divided signal to reduce noise of the second frequency divided signal for generating a second noise-reduced frequency divided signal.

11. The dividing method of claim 8, wherein the step of referring to the first noise-reduced frequency divided signal and the second frequency divide signal for generating the second noise-reduced frequency divided signal comprises:
generating the first noise-reduced frequency divided signal by referring to a signal level transition point of the first frequency divided signal to sample the second clock signal.

12. The dividing method of claim 11, wherein the step of generating the first noise-reduced frequency divided signal by referring to the signal level transition point of the first frequency divided signal for generating the first noise-reduced frequency divided signal comprises:
generating the first noise-reduced frequency divided signal by performing a data latch operation upon the second clock signal according to the first frequency divided signal.

13. The dividing method of claim 12, wherein the step of generating the first noise-reduced frequency divided signal by performing the data latch operation upon the second clock signal according to the first frequency divided signal comprises:
providing a latch unit having a data input terminal, a data output terminal and an enabling input terminal;
coupling the first frequency divided signal to the enabling input terminal;
coupling the second clock signal to the data input terminal; and
generating the first noise-reduced frequency divided signal at the data output terminal.
